(19) United States
(12) Patent Application Publication
(10) Pub. No.: US 2015/0372236 A1
(43) Pub. Date: Dec. 24, 2015

(54) WELL-ORIENTED 6,13-BIS(TRIISOPROPYLSILYLETHYNYL) PENTACENE CRYSTALS AND A TEMPERATURE-GRADIENT METHOD FOR PRODUCING THE SAME

(71) Applicant: THE BOARD OF TRUSTEES OF THE UNIVERSITY OF ALABAMA, Tuscaloosa, AL (US)

(72) Inventors: Dawen LI, Tuscaloosa, AL (US); Kyeiwaa ASARE-YEBOAH, Tuscaloosa, AL (US); Rachel M. FRAZIER, Tuscaloosa, AL (US)

(21) Appl. No.: 14/767,139

(22) PCT Filed: Apr. 5, 2013
(86) PCT No.: PCT/US2013/035463

§ 371 Date: Aug. 11, 2015

Related U.S. Application Data
(60) Provisional application No. 61/763,202, filed on Feb. 11, 2013.

(51) Int. Cl. H01L 51/00; C07F 7/08

(52) U.S. Cl. CPC H01L 51/0026; H01L 51/0003; C07F 7/0809; H01L 51/0545

(57) ABSTRACT

Disclosed herein are temperature-gradient methods of producing well-oriented TIPS pentacene crystals and films comprising establishing a temperature gradient on a substrate to produce a heated substrate having a lower temperature portion at a first temperature and a higher temperature portion at a second temperature and applying a solution comprising 6,13-bis(triisopropylsilylethynyl)pentacene to the heated substrate, driving crystallization from the lower temperature portion of the substrate to the higher temperature portion of the substrate.

### FIELD

The present disclosure relates generally to TIPS pentacene (e.g., 6,13-bis(triisopropylsilylethynyl)pentacene) films having, for instance, controlled film morphology, uniformity, consistency of crystal orientation, single crystal size, and/or enhanced areal coverage, and methods of making and using the same, as well as articles comprising said TIPS pentacene films.

### BACKGROUND

TIPS pentacene (e.g., 6,13-bis(triisopropylsilylethynyl)pentacene as shown below)

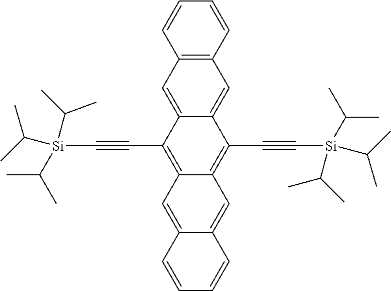 [SMILES: CC(C)[Si](C#Cc1c2cc3ccccc3cc2c(C#C[Si](C(C)C)(C(C)C)C(C)C)c2cc3ccccc3cc12)(C(C)C)C(C)C]

is a solution-processable organic semiconductor. TIPS pentacene has a variety of beneficial properties including, but not limited to, its excellent carrier transport, stability in air, high mobility (for instance, greater than 4.0 cm²/Vs reported), and low-cost processing at room temperature. Because of its beneficial properties, TIPS pentacene has been studied for use in a variety of applications including, but not limited to, as an active channel material for organic thin-film transistors (OTFTs), and for applications in organic electronics such as flexible displays, organic light-emitting diodes, organic photovoltaics, and nonlinear optics.

Despite the beneficial properties of TIPS pentacene, TIPS pentacene thin films can be acutely anistropic when they are grown from, for instance, simple solution drop casting. As shown in FIG. 1, each individual TIPS pentacene crystal made from simple solution drop casting can grow in random directions, leading to large variations in OTFT performance. Other deposition methods (e.g., spin coating, dip coating) from solution have been tried in an effort to attain well-oriented TIPS pentacene crystals. None of those approaches, however, achieves controlled film morphology in terms of consistency of crystal orientation, single crystal size, or large areal coverage. For instance, the spin-coating method can produce continuous and relatively uniform TIPS pentacene films, but the single crystal sizes can be small, resulting in low charge transport mobility between grain boundaries. TIPS pentacene films deposited from dip coating can produce uniformity of crystal orientation, but large gaps between each single crystal can result in poor crystal coverage on the substrates, as shown in FIG. 1. This also reduces the OTFT performance because less crystal material can be available for charge transport.

Accordingly, improved TIPS pentacene films having, for instance, controlled film morphology, uniformity, consistency of crystal orientation, single crystal size, and/or enhanced areal coverage on substrates and methods of making and using the same, as well as articles comprising said TIPS pentacene films, are desired. The subject matter disclosed herein addresses these and other desires.

### SUMMARY

In accordance with the purposes of the disclosed materials, compounds, compositions, and methods, as embodied and broadly described herein, the disclosed subject matter, in one aspect, relates to compounds and compositions and methods for preparing and using such compounds and compositions. In a further aspect, the disclosed subject matter relates to methods for making well-oriented TIPS pentacene crystals and films comprising establishing a temperature gradient on a substrate to produce a heated substrate having a lower temperature portion at a first temperature and a higher temperature portion at a second temperature, and applying a solution comprising TIPS pentacene to the heated substrate to drive crystallization from the lower temperature portion of the substrate to the higher temperature portion of the substrate. In some aspects, the temperature gradient is established on the substrate by establishing a temperature gradient on a plate such that the plate has a lower-temperature end and a higher-temperature end, and placing the substrate on the plate such that a first portion of the substrate is on the low-temperature end of the plate and a second portion of the substrate is on the high-temperature end of the plate for a set time to produce a heated substrate having a lower temperature portion at the first temperature and a higher temperature portion at the second temperature. In some examples, the temperature gradient is established on the plate by heating the plate to the first temperature and applying increased heat to the second end of the plate to create the higher temperature end.

In some examples, the solution comprising TIPS pentacene further comprises toluene, a high boiling point solvent, or a mixture thereof. In some examples, the solution has a concentration of 5 mg/mL of TIPS pentacene in toluene and a high boiling-point solvent. In some examples, the toluene is present in an amount of from 75% to 85% by volume. In some examples, the high boiling-point solvent is present in an amount of from 15% to 25% by volume. The high boiling-point solvent can be, for instance, dimethyl formamide.

The solution can be applied to the substrate, for instance, by drop casting. In some examples, the plate comprises metal. In some examples, the substrate comprises silicon. The second temperature on the plate and/or on the substrate can be greater than the first temperature by an amount of from 2° C. to 28° C. In some examples, the first temperature is from 22° C. to 30° C. In some examples, the first temperature is 26° C. and the second temperature is 28° C.

Well-oriented 6,13-bis(triisopropylsilylethynyl)pentacene crystals and films are also disclosed herein, as well as articles comprising said films.

Additional advantages will be set forth in part in the description that follows, and in part will be obvious from the description, or may be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

### BRIEF DESCRIPTION OF THE FIGURES

The accompanying Figures, which are incorporated in and constitute a part of this specification, illustrate several aspects described below.

FIG. 1 is a polarized optical image of TIPS pentacene crystals grown from simple solution drop casting. The crystals grow in random directions with wide gaps (poor aerial coverage), which lead to large variations in OTFT performance.

FIG. 2 is a polarized image of TIPS pentacene crystals grown with the application of approximately 2° C. temperature gradient. Uniform crystal orientation is demonstrated with an improved aerial coverage of approximately 75%, hence a reduction in the gaps.

FIG. 3 is a polarized image of TIPS pentacene crystals grown with the application of approximately 2.5° C. temperature gradient. The increase in temperature gradient increases the crystal width, which in turn decreases the gaps. The film coverage is approximately 90% with aligned crystal growth.

FIG. 4 is a polarized image of TIPS pentacene crystals grown with the application of approximately 4° C. temperature gradient. Large crystal sizes and well-oriented plate-like crystals are demonstrated with a film coverage of approximately 90%.

FIG. 5 is a polarized image of TIPS pentacene crystals grown with the application of approximately 5° C. temperature gradient. A further increase in the temperature gradient still generates the excellent areal coverage (approximately 93.5%) and crystal orientation, but produces a slight decrease in crystal sizes due to an increase in nucleation seeds.

FIG. 6 is a polarized image of TIPS pentacene crystals grown with the application of approximately 6° C. temperature gradient. Depicted is the exceptional crystal alignment with a film coverage of approximately 95% but a slight drop in the individual crystal width due to the rise in nucleation seeds.

FIG. 7 is an optical image of TIPS pentacene film grown from a double solvent solution (Toluene and DMF) with the application of a temperature gradient of approximately 2° C. The figure illustrates uniform crystal orientation, large single crystal sizes, and great areal coverage. The insert is a magnified polarized image of the TIPS pentacene film.

FIG. 8 is an optical image of TIPS pentacene crystals grown via temperature gradient from a double solvent solution on a silicon substrate. The uniform orientation of the crystals is demonstrated on a broad perspective.

FIG. 9 depicts output (I_{D} versus V_{DS}) characteristics of one embodiment of a top contact OTFTs based on the 5° C. temperature gradient grown TIPS pentacene film from a 7 mg/mL solution. Extracted mobility=0.045927 cm²/Vs and V_{Th}=4 V.

FIG. 10 depicts output (I_{D} versus V_{DS}) characteristics of one embodiment of top contact OTFTs based on the 5° C. temperature gradient grown TIPS pentacene film from a 7 mg/mL solution. Extracted mobility=0.053192 cm²/Vs and V_{Th}=6.5 V.

FIG. 11 depicts output (I_{D} versus V_{DS}) characteristics of one embodiment of top contact OTFTs based on the 5° C. temperature gradient grown TIPS pentacene film from a 7 mg/mL solution. Extracted mobility=0.017887 cm²/Vs and V_{Th}=6.9 V.

FIG. 12 depicts output (I_{D} versus V_{DS}) characteristics of one embodiment of top contact OTFTs based on the 5° C. temperature gradient grown TIPS pentacene film from a 7 mg/mL solution. Extracted mobility=0.030699 cm²/Vs and V_{Th}=8.5 V.

FIG. 13 depicts output (I_{D} versus V_{DS}) characteristics of one embodiment of top contact OTFTs based on the 5° C. temperature gradient grown TIPS pentacene film from a 7 mg/mL solution. Extracted mobility=0.058645 cm²/Vs and V_{Th}=11 V.

FIG. 14 depicts output (I_{D} versus V_{DS}) characteristics of one embodiment of top contact OTFTs based on the 5° C. temperature gradient grown TIPS pentacene film from a 7 mg/mL solution. Extracted mobility=0.039501 cm²/Vs and V_{Th}=6.6 V.

FIG. 15 depicts output (I_{D} versus V_{DS}) characteristics of top contact OTFTs based on TIPS pentacene film grown from simple drop cast. Extracted mobility=0.001388 cm²/Vs and V_{Th}=4.5 V.

FIG. 16 depicts output (I_{D} versus V_{DS}) characteristics of top contact OTFTs based on TIPS pentacene film grown from simple drop cast. Extracted mobility=0.0021036 cm²/Vs and V_{Th}=1.7 V.

FIG. 17 depicts output (I_{D} versus V_{DS}) characteristics of top contact OTFTs based on TIPS pentacene film grown from simple drop cast. Extracted mobility=0.0016766 cm²/Vs and V_{Th}=2.4 V.

FIG. 18 depicts output (I_{D} versus V_{DS}) characteristics of top contact OTFTs based on TIPS pentacene film grown from simple drop cast. Extracted mobility=0.0015942 cm²/Vs and V_{Th}=4.5 V.

FIG. 19 depicts output (I_{D} versus V_{DS}) characteristics of top contact OTFTs based on TIPS pentacene film grown from simple drop cast. Extracted mobility=0.0014776 cm²/Vs and V_{Th}=2.5 V.

FIG. 20 depicts output (I_{D} versus V_{DS}) characteristics of top contact OTFTs based on TIPS pentacene film grown from simple drop cast. Extracted mobility=0.0023934 cm²/Vs and V_{Th}=2.5 V.

### DETAILED DESCRIPTION

The present disclosure relates, in one aspect, to methods of producing well-oriented TIPS pentacene crystals by having a temperature gradient on a substrate during crystal growth. The application of a temperature gradient to guide the TIPS-pentacene crystal growth can direct crystal formation and allow for a more controlled film morphology, uniformity, and crystal orientation, leading to enhanced OTFT performance. Because crystal morphology of the TIPS pentacene is a strong function of the solvent characteristics, a mixed solvent comprising, for instance, toluene and/or a high boiling point solvent, such as dimethyl formamide (DMF), can be employed to achieve well-oriented TIPS pentacene crystals.

The methods disclosed herein overcome drawbacks to conventional techniques to deposit films from solution, specifically poor coverage and orientation associated with solution casting techniques and cost associated with physical deposition techniques. In particular, crystal growth from solution offers a low-cost, high performance route to get oriented crystals. Crystal growth from solution can work by manipulating the concentration within the solution to create regions where the concentration is above the solubility limit of the solution. This can result in regions of supersaturation, which can drive crystal growth from regions of higher concentration to regions of lower concentration. Supersaturation can be controlled by several techniques including, but not limited to, thermal gradient, evaporation, slow cooling, and double solvent systems. The thermal gradient approach can be suitable for organic electronic applications because it can be easy to control an optimal thermodynamic system.

The thermal gradient approach is based on applying a difference in temperatures to a solution to control the concentration within the solution. The concentration depends on temperature and by applying two or more different temperatures to a single solution, supersaturation can be imposed, whereby at least one portion of the solution is above the solubility limit and at least another portion is below, which can create a thermodynamic condition that can drive crystal growth from the supersaturated region to the other region. The level of supersaturation can be optimized to grow the best crystals in terms of size. Too low of a supersaturation level can result in poor coverage and too high a level can result in smaller crystals. As supersaturation increases, the number of nucleation sites increase, which at some point can compete with the ability of already formed crystals to continue to grow. Maintaining a thermodynamic balance can allow crystals to form and grow without being disrupted by new crystal formation. The thermal gradient approach offers a convenient way to maintain thermodynamic balance.

A detailed procedure of temperature-gradient aided TIPS pentacene growth is disclosed herein. For example, a plate can be uniformly heated up to a first temperature. In some examples, the plate comprises metal, metal alloy, ceramic, ceramic alloy, glass, plastic, or combinations thereof. In some examples, the first temperature is 20° C. or greater (e.g., 22° C. or greater, 24° C. or greater, 26° C. or greater, 28° C. or greater, 30° C. or greater, 32° C. or greater, 34° C. or greater, 36° C. or greater, 38° C. or greater, 40° C. or greater, 42° C. or greater, 44° C. or greater, 46° C. or greater, 48° C. or greater, 50° C. or greater, 52° C. or greater, 54° C. or greater, 56° C. or greater, or 58° C. or greater), with the upper limit being the second temperature as noted herein. In some examples, the first temperature is 60° C. or less (e.g., 58° C. or less, 56° C. or less, 54° C. or less, 52° C. or less, 50° C. or less, 48° C. or less, 48° C. or less, 48° C. or less, 48° C. or less, 48° C. or less, 48° C. or less, 48° C. or less, 48° C. or less, 48° C. or less, 48° C. or less, 48° C. or less, 48° C. or less, 48° C. or less, 48° C. or less, or 23° C. or less), with the lower limit being −72° C. In some examples, the first temperature is from 20° C. to 60° C. (e.g., from 22° C. to 58° C., from 26° C. to 54° C., from 30° C. to 50° C., from 34° C. to 46° C., or from 38° C. to 42° C.).

A temperature gradient is established on the plate. By temperature gradient is meant a change in temperature with displacement in a given direction from a given reference point. In some examples, the temperature gradient can be established by increasing the temperature on a portion of the plate. Alternatively, a temperature gradient can be established by decreasing the temperature on a portion of the plate. In some examples, the temperature gradient is established on the plate, resulting in a heated plate having the first temperature on a first side of the heated plate and a second temperature on a second side of the heated plate. Although the first side of the heated plate is the first temperature and the second side of the heated plate is the second temperature, the temperature gradient, by nature, can have a steady change in temperature from one side to another. By referring to various sides of the plate it is not meant to imply that the edges of the plate are referenced, as a temperature gradient can be established by referencing two internal locations of the plate. What is important is that a temperature gradient exists along the path of TIPS pentacene crystallization, and this path can be anywhere on the plate.

In some examples, the difference between the first temperature and the second temperature is 2° C. or greater (e.g., 4° C. or greater, 6° C. or greater, 8° C. or greater, 10° C. or greater, 12° C. or greater, 14° C. or greater, 16° C. or greater, 18° C. or greater, 20° C. or greater, 22° C. or greater, 24° C. or greater, or 26° C. or greater). In some examples, the difference between the first temperature and the second temperature is 28° C. or less (e.g., 26° C. or less, 24° C. or less, 22° C. or less, 20° C. or less, 18° C. or less, 16° C. or less, 14° C. or less, 12° C. or less, 10° C. or less, 8° C. or less, 6° C. or less, or 4° C. or less). In some examples, the difference between the first temperature and the second temperature is from 2° C. to 28° C. (e.g., from 4° C. to 26° C., from 6° C. to 24° C., from 8° C. to 22° C., from 10° C. to 20° C., from 12° C. to 18° C., from 14° C. to 16° C.).

In some examples, the second temperature is greater than the first temperature and can be 20° C. or greater (e.g., 22° C. or greater, 24° C. or greater, 26° C. or greater, 28° C. or greater, 30° C. or greater, 32° C. or greater, 34° C. or greater, 36° C. or greater, 38° C. or greater, 40° C. or greater, 42° C. or greater, 44° C. or greater, 46° C. or greater, 48° C. or greater, 50° C. or greater, 52° C. or greater, 54° C. or greater, 56° C. or greater, or 58° C. or greater), with the upper limit being the decomposition temperature of TIPS pentacene. In some examples, the second temperature is 60° C. or less (e.g., 58° C. or less, 56° C. or less, 54° C. or less, 52° C. or less, 50° C. or less, 48° C. or less, 48° C. or less, 48° C. or less, 48° C. or less, 48° C. or less, 48° C. or less, 48° C. or less, 48° C. or less, 48° C. or less, 48° C. or less, 48° C. or less, 48° C. or less, 48° C. or less, 48° C. or less, or 23° C. or less), with the lower limit being the first temperature as noted herein. In some examples, the second temperature is from 20° C. to 60° C. (e.g., from 22° C. to 58° C., from 26° C. to 54° C., from 30° C. to 50° C., from 34° C. to 46° C., or from 38° C. to 42° C.).

The temperature gradient can be established on the plate in any manner capable of creating a temperature difference along the length of the plate. In some examples, the temperature gradient is established by using a wire heater, a metal plate heater, a ceramic plate heater, a platen, a hotplate, a substrate heater, or combinations thereof.

In some examples, a substrate can be placed on the plate. In some examples, the substrate comprises silicon. In some examples, the substrate comprises silicon dioxide. The substrate can be placed on the plate at any time. In some examples, the substrate can be placed on the plate before the plate is heated to a first temperature. In some examples, the substrate can be placed on the plate while the plate is being heated to a first temperature. In some examples, the substrate can be placed on the plate after the plate is heated to a first temperature. In some examples, the substrate can be placed on the plate before the temperature gradient is established. In some examples, the substrate can be placed on the plate while the temperature gradient is being established. In some examples, the substrate can be placed on the plate after the temperature gradient is established.

Regardless of when the substrate is placed on the plate, the substrate is left on the plate for a time sufficient to allow a temperature gradient to be established in the substrate. In some examples, the time to establish a temperature gradient to be established on the substrate can be 1 minute or greater (e.g., 2 minutes or greater, 4 minutes or greater, 6 minutes or greater, 8 minutes or greater, 10 minutes or greater, 15 minutes or greater, 20 minutes or greater, 30 minutes or greater, 1 hour or greater, or 2 hours or greater). In some examples, the time to establish a temperature gradient to be established on the substrate can be 4 hours or less (e.g., 2 hours or less, 1 hour or less, 30 minutes or less, 20 minutes or less, 15 minutes or less, 10 minutes or less, 8 minutes or less, 6 minutes or less, 4 minutes or less, or 2 minutes or less). In some examples, the time to establish a temperature gradient to be established on the substrate can be from 1 minute to 4 hours (e.g., 10 minutes to 3 hours, 20 minutes to 2 hours, 30 minutes to 1 hour). Once the temperature gradient is established on the substrate, a first side (or portion or section) of the substrate will have the first temperature of the plate and a second side (or portion or section) of the substrate will have the second temperature of the plate. Although the side of the substrate is the first temperature and the second side of the substrate is the second temperature, the temperature gradient, by nature, can have a steady change in temperature from one side to another.

A TIPS-pentacene solution is added to the substrate subjected to the temperature gradient. Alternatively, if no substrate is added to the plate, the TIPS-solution can be added directly to the plate, in which case the plate acts as and can be referred to as the substrate. The TIPS-pentacene solution can comprise TIPS pentacene, toluene, a high boiling-point solvent, or a mixture thereof. In some examples, the high boiling-point solvent includes DMF. In some examples, the high boiling-point solvent includes dimethyl sulfoxide, m-cresol, N-Methyl-2-pyrrolidone, chlorobenzene, or xylene.

The TIPS-pentacene solution can be prepared by any method known in the art. In some examples, the TIPS-pentacene solution is prepared from TIPS pentacene in toluene and DMF. In some examples, the concentration of TIPS pentacene can be 1 mg/mL or greater (e.g., 2 mg/mL or greater, 4 mg/mL or greater, 6 mg/mL or greater, 8 mg/mL or greater, 10 mg/mL or greater, 12 mg/mL or greater, 14 mg/mL or greater, 16 mg/mL or greater, 18 mg/mL or greater, 20 mg/mL or greater, 22 mg/mL or greater, 24 mg/mL or greater, 26 mg/mL or greater, 28 mg/mL or greater, 30 mg/mL or greater, 32 mg/mL or greater, 34 mg/mL or greater, 36 mg/mL or greater, 38 mg/mL or greater, 40 mg/mL or greater, 42 mg/mL or greater, 44 mg/mL or greater, 46 mg/mL or greater, or 48 mg/mL or greater). In some examples, the concentration of TIPS pentacene can be 50 mg/mL or less (e.g., 48 mg/mL or less, 46 mg/mL or less, 44 mg/mL or less, 42 mg/mL or less, 40 mg/mL or less, 38 mg/mL or less, 36 mg/mL or less, 34 mg/mL or less, 32 mg/mL or less, 30 mg/mL or less, 28 mg/mL or less, 26 mg/mL or less, 24 mg/mL or less, 22 mg/mL or less, 20 mg/mL or less, 18 mg/mL or less, 16 mg/mL or less, 14 mg/mL or less, 12 mg/mL or less, 10 mg/mL or less, 8 mg/mL or less, 6 mg/mL or less, 4 mg/mL or less, or 2 mg/mL or less). In some examples, the concentration of TIPS pentacene can be from 1 mg/mL to 50 mg/mL (e.g., from 2 mg/mL to 48 mg/mL, from 5 mg/mL to 45 mg/mL, from 10 mg/mL to 35 mg/mL, from 15 mg/mL to 25 mg/mL). In some examples, the toluene can be present in an amount of 60% by volume or greater (e.g., 65% by volume or greater, 70% by volume or greater, 75% by volume or greater, 80% by volume or greater, 85% by volume or greater, 90% by volume or greater, or 95% by volume or greater). In some examples, the toluene can be present in an amount of 98% by volume or less (e.g., 95% by volume or less, 90% by volume or less, 85% by volume or less, 80% by volume or less, 75% by volume or less, 70% by volume or less, or 65% by volume or less). In some examples, the toluene can be present in an amount of from 60% to 98% by volume (e.g., from 65% to 95% by volume, from 70% to 90% by volume, or from 75% to 85% by volume). In some examples, the DMF can be present in an amount of 2% by volume or greater (e.g., 5% by volume or greater, 10% by volume or greater, 15% by volume or greater, 20% by volume or greater, or 30% by volume or greater). In some examples, the DMF can be present in an amount of 40% by volume or less (e.g., 35% by volume or less, 30% by volume or less, 25% by volume or less, 20% by volume or less, 15% by volume or less, 10% by volume or less, or 5% by volume or less). In some examples, the DMF can be present in an amount of from 2% to 40% by volume (e.g., from 5% to 35% by volume, from 10% to 30% by volume, or from 15% to 25% by volume). The TIPS-pentacene solution can be subjected to any mixing method that aids the TIPS pentacene to dissolve in the solvent (e.g., a toluene/DMF mixture). In some examples, the mixing method occurs until the solute is completely dissolved in the solvent. In some examples, the mixing method is ultrasonic agitation, stirring, vortexing, shaking, or combinations thereof. In some examples, the TIPS-pentacene solution can be mixed for 20 minutes or greater (e.g., 25 minutes or greater, 30 minutes or greater, 35 minutes or greater, 40 minutes or greater, or 45 minutes or greater). In some examples, the TIPS-pentacene solution can be mixed for 50 minutes or less (e.g., 45 minutes or less, 40 minutes or less, 35 minutes or less, 30 minutes or less, or 25 minutes or less). In some examples, the TIPS-pentacene solution can be mixed from 20 minutes to 50 minutes (e.g., from 25 minutes to 45 minutes, from 30 minutes to 40 minutes, from 32 minutes to 37 minutes).

The TIPS-pentacene solution can be added to the substrate by any method known in the art. In some examples, the TIPS-pentacene solution can be added to the substrate by drop casting. In other methods the TIPS-pentacene solution can be added by spin coating or dip coating. Without wishing to be bound to theory, the temperature gradient on the substrate can lead to a difference in the solubility of the solute along the substrate and can drive crystallization from the higher temperature side (portion or region) to the lower temperature side (portion or region). Solvent evaporation can be modulated by the amount of added high boiling point solvent (e.g., DMF). Application of the high boiling point solvent along with the toluene solvent annealing can improve the areal coverage of the substrate as well as the quality of the TIPS pentacene crystals. The uniform morphology of the TIPS pentacene films on the entire substrate proves the effectiveness of the temperature-gradient approach. Comparing these TIPS pentacene crystals to those grown from other methods, it can be clearly seen that the temperature-gradient approach has its crystals growing in a uniform orientation with a larger areal coverage across the substrate and big, single crystal sizes in general, as opposed to the crystals formed from the simple drop casting, dip coating, and spin coating methods.

Overall, the successful improvement of the crystal orientation and simultaneous increase in crystal coverage on the substrate as seen from the optical images clearly attests the effectiveness of the temperature-gradient approach, establishing once again the reason for the temperature-gradient method being a better technique for growing the TIPS pentacene. This is shown by application to organic transistors, which have improved electronic properties compared to conventional casting.

Transistors having improved electrical properties are also disclosed herein. In some examples, the transistors disclosed herein have an extracted mobility of 0.005 cm²/Vs or greater (e.g., 0.01 cm²/Vs or greater, 0.012 cm²/Vs or greater, 0.014 cm²/Vs or greater, 0.016 cm²/Vs or greater, 0.018 cm²/Vs or greater, 0.02 cm²/Vs or greater, 0.022 cm²/Vs or greater, 0.024 cm²/Vs or greater, 0.026 cm²/Vs or greater, 0.028 cm²/Vs or greater, 0.03 cm²/Vs or greater, 0.032 cm²/Vs or greater, 0.034 cm²/Vs or greater, 0.036 cm²/Vs or greater, 0.038 cm²/Vs or greater, 0.04 cm²/Vs or greater, 0.042 cm²/Vs or greater, 0.044 cm²/Vs or greater, 0.046 cm²/Vs or greater, 0.048 cm²/Vs or greater, 0.05 cm²/Vs or greater, 0.052 cm²/Vs or greater, 0.054 cm²/Vs or greater, 0.056 cm²/Vs or greater, 0.058 cm²/Vs or greater, 0.06 cm²/Vs or greater, 0.062 cm²/Vs or greater, 0.064 cm²/Vs or greater, 0.066 cm²/Vs or greater, 0.068 cm²/Vs or greater, 0.07 cm²/Vs or greater, 0.072 cm²/Vs or greater, 0.074 cm²/Vs or greater, 0.076 cm²/Vs or greater, or 0.078 cm²/Vs or greater). In some examples, the transistors disclosed herein have an extracted mobility of 0.08 cm²/Vs or less (e.g., 0.078 cm²/Vs or less, 0.076 cm²/Vs or less, 0.074 cm²/Vs or less, 0.072 cm²/Vs or less, 0.07 cm²/Vs or less, 0.068 cm²/Vs or less, 0.066 cm²/Vs or less, 0.064 cm²/Vs or less, 0.062 cm²/Vs or less, 0.06 cm²/Vs or less, 0.058 cm²/Vs or less, 0.056 cm²/Vs or less, 0.054 cm²/Vs or less, 0.052 cm²/Vs or less, 0.05 cm²/Vs or less, 0.048 cm²/Vs or less, 0.046 cm²/Vs or less, 0.044 cm²/Vs or less, 0.042 cm²/Vs or less, 0.04 cm²/Vs or less, 0.038 cm²/Vs or less, 0.036 cm²/Vs or less, 0.034 cm²/Vs or less, 0.032 cm²/Vs or less, 0.03 cm²/Vs or less, 0.028 cm²/Vs or less, 0.026 cm²/Vs or less, 0.024 cm²/Vs or less, 0.022 cm²/Vs or less, 0.02 cm²/Vs or less, 0.018 cm²/Vs or less, 0.016 cm²/Vs or less, 0.014 cm²/Vs or less, 0.012 cm²/Vs or less, 0.01 cm²/Vs or less). In some examples, the transistors have an extracted mobility of from 0.005 cm²/Vs to 0.08 cm²/Vs (e.g., 0.015 cm²/Vs to 0.06 cm²/Vs, 0.025 cm²/Vs to 0.055 cm²/Vs, 0.03 cm²/Vs to 0.05 cm²/Vs, or from 0.035 cm²/Vs to 0.045 cm²/Vs). In some examples, the transistors disclosed herein have V_{Th} of 2 V or greater (e.g., 3 V or greater, 3.5 V or greater, 4 V or greater, 4.5 V or greater, 5 V or greater, 6 V or greater, 6.5 V or greater, 7 V or greater, 7.5 V or greater, 8 V or greater, 8.5 V or greater, 9 V or greater, 9.5 V or greater, 10 V or greater, 10.5 V or greater, 11 V or greater, 11.5 V or greater, 12 V or greater, 12.5 V or greater, 13 V or greater, 13.5 V or greater, 14 V or greater, 14.5 V or greater). In some examples, the transistors disclosed herein have V_{Th} of 15 V or less (e.g., 14.5 V or less, 14 V or less, 13.5 V or less, 13 V or less, 12.5 V or less, 12 V or less, 11.5 V or less, 11 V or less, 10.5 V or less, 10 V or less, 9.5 V or less, 9 V or less, 8.5 V or less, 8 V or less, 7.5 V or less, 7 V or less, 6.5 V or less, 6 V or less, 5.5 V or less, 5 V or less, 4.5 V or less, 4 V or less, 3.5 V or less, 3 V or less, or 2.5 V or less). In some examples, the transistors disclosed herein have V_{Th} of from 2 V to 15 V (e.g., from 4 V to 11 V, from 5 V to 10 V, from 6V to 9 V, or from 7 V to 8 V).

The well oriented TIPS pentacene films can be used to prepare printed and thin film transistors (e.g., organic thin film transistors), by methods known in the art. Such transistors can in turn be included in a variety of articles including, but not limited to, OLED displays, LCD displays, LCD-TFT displays, AM-OLED displays, integrated circuits for lighting, sensors, RFID tags, solar cells, display backpanes, sensors (e.g., temperature, pressure, radiation, etc.), or any application where logic circuitry is used.

Other than in the examples, or where otherwise noted, all numbers expressing quantities of ingredients, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present disclosure.

As used in the specification and the appended claims, the singular forms “a,” “an,” and “the” include plural referents unless the context clearly dictates otherwise.

Notwithstanding that the numerical ranges and parameters setting forth the broad scope of the disclosure are approximations, unless otherwise indicated the numerical values set forth in the examples are reported as precisely as possible. Any numeric value, however, inherently contains certain errors necessarily resulting from the standard deviation found in their respective testing methods. Finally, the various titles and section headers used throughout the specification are presented merely for the convenience of the reader and are not intended to limit the disclosure. The disclosure herein is not limited to specific methods or reagents. Further, the terminology used herein is for the purpose of describing particular aspects only and is not intended to be limiting.

By way of non-limiting illustration, examples of certain examples of the present disclosure are given below.

### EXAMPLES

### Comparative Example 1

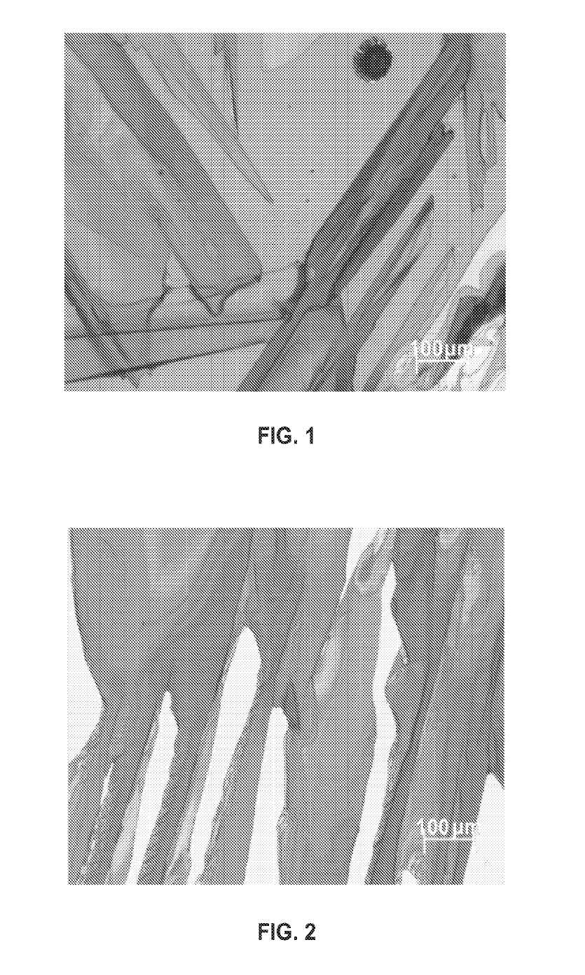

TIPS pentacene was purchased and used without further purification from Sigma-Aldrich and toluene was purchased from Alfa Aesar (a Johnson Matthey Company). A 7 mg/mL TIPS pentacene/toluene solution was drop cast onto a heavily doped n-type silicon substrate with a 250-nm-thick thermal oxide insulation layer, which was placed on a leveled petri dish. Using a 3 mL syringe, three drops of toluene were dispensed onto the petri dish and allowed to create a solvent vapor during the anneal. The petri dish was covered with a layer of parafilm and the TIPS pentacene was allowed to crystallize. FIG. 1 shows a polarized optical image of TIPS pentacene crystals grown from simple solution drop casting. The crystals grow in random directions with wide gaps (poor aerial coverage).

### Example 2

TIPS pentacene was purchased and used without further purification from Sigma-Aldrich and toluene was purchased from Alfa Aesar (a Johnson Matthey Company). A metal plate was heated by an Omega temperature controller and a heavily insulated heat tape. The temperature controller was set to 50° C. and the metal plate was allowed to rest for at least 3 hours to establish uniform heat. One side of a petri dish was placed on the uniformly heated metal plate and the other end was placed on a support in ambient. The 50° C. set temperature resulted in a 28° C. upper temperature limit and a 26° C. lower temperature limit (2° C. degrees difference in temperature) on the petri dish. To establish a stable temperature gradient, the petri dish was allowed to heat up for 30 minutes. A 7 mg/mL TIPS pentacene/toluene solution was prepared for the crystal growth. Tilt in all directions on the metal plate and the petri dish was eliminated and confirmed using a bubble level. A (2×2.4) cm² substrate, the same type as was used in Comparative Example 1, was strategically placed on the petri dish such that one end of it was on the side of the petri dish placed on the heated plate and the other end was on the side of the petri dish which was on a support in ambient. A steady increase in temperature from one end of the substrate to the other was then established, and the substrate was permitted to rest for 15 minutes. Then, 250 μL of the solution was drop cast onto the substrate. Next, 0.8-0.9 mL of toluene was used to anneal the closed system, which was covered with a few layers of parafilm to increase the humidity within it to control solvent evaporation, and therefore rely on crystal growth from the thermal gradient.

The TIPS pentacene crystallization occurred over a 45- to 75-minute period, depending on the type of gradient used. The smaller the gradient the more the time needed for crystallization; this is mainly due to the fact that the upper and lower temperature limits for the smaller gradients were lower compared respectively to those of the larger gradients. The temperature gradient brought about a difference in the solubility of the solute along the substrate, driving the crystal growth from the lower temperature end to the higher temperature end of the substrate.

FIG. 2 shows polarized image of TIPS pentacene crystals grown with the application of the 2° C. degrees temperature gradient. Uniform crystal orientation is demonstrated with an improved aerial coverage of approximately 75%, showing a significant improvement over simple drop casting as described in Comparative Example 1.

### Example 3

A TIPS film was grown as described in Example 2; however, the thermal gradient was increased. The temperature controller was set to 60° C., which heated one end of the petri dish to 29.35° C. and the other end to 26.85° C. A temperature gradient of 2.5° C. degrees was established using the method as described in Example 2.

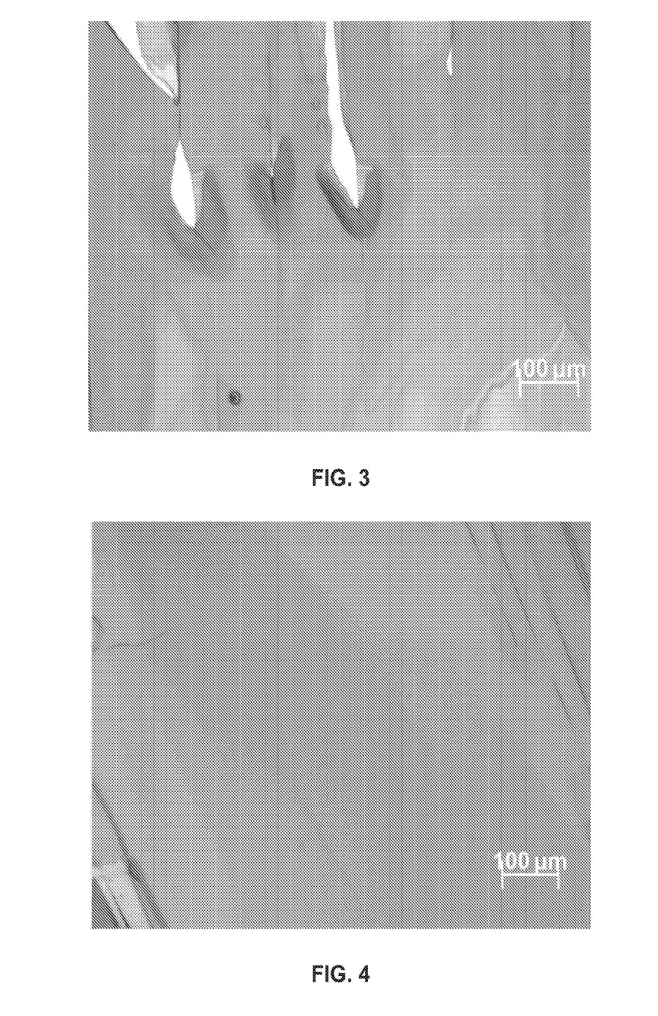

FIG. 3 shows a polarized image of TIPS pentacene crystals grown with the application of 2.5° C. degrees temperature gradient. The increase in temperature gradient increases the crystal width, which in turn decreases the gaps. The film coverage is approximately 90% with aligned crystal growth.

### Example 4

A TIPS film was grown as described in Example 2; however, the thermal gradient was further increased. The temperature controller was set to 70° C., which heated one end of the petri dish to 31° C. and the other end to 27° C. A temperature gradient of 4° C. degrees was established as described in Example 2.

FIG. 4 shows a polarized image of TIPS pentacene crystals grown with the application of 4° C. degrees temperature gradient. Large crystal sizes and well-oriented plate-like crystals are demonstrated with a film coverage of approximately 90%.

### Example 5

A TIPS film was grown as described in Example 2; however, the thermal gradient used was still further increased. The temperature controller was set to 80° C., which heated one end of the petri dish to 32.1° C. and the other end to 27.1° C. A temperature gradient of 5° C. degrees was established as described in Example 2.

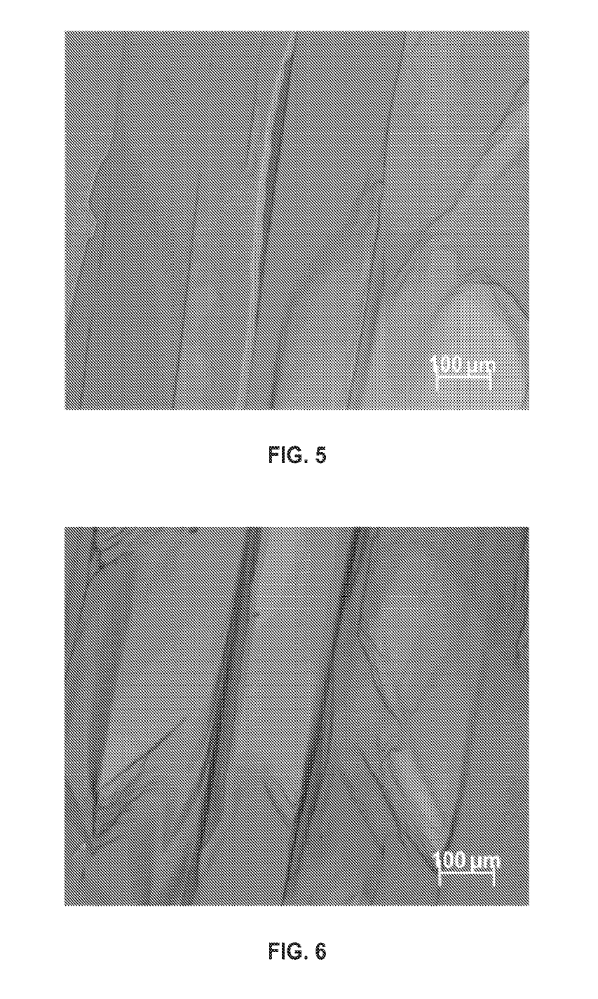

FIG. 5 shows a polarized image of TIPS pentacene crystals grown with the application of 5° C. degrees temperature gradient. A further increase in the temperature gradient still generates the excellent areal coverage (approximately 93.5%) and crystal orientation, but produces a slight decrease in crystal sizes. Without wishing to be bound to theory, Applicants believe the decrease in crystal sizes is attributed to an increase in supersaturation, which drives an increase in nucleation that outcompetes the ability of the crystals to grow larger.

### Example 6

A TIPS film was grown as described in Example 2; however, the thermal gradient was increased. The temperature controller was set to 90° C., which heated one end of the petri dish to 35.6° C. and the other end to 28.6° C. A temperature gradient of 6° C. degrees was established as described in Example 2.

FIG. 6 shows a polarized image of TIPS pentacene crystals grown with the application of 6° C. degrees temperature gradient. Depicted is the exceptional crystal alignment with a film coverage of approximately 95% but a slight drop in the individual crystal width. This further suggests that the thermal gradient approach is driving crystal growth, because an increase in temperature difference leads to an increase in supersaturation to the point that nucleation sites continue to increase resulting in smaller sized crystals.

### Example 7

To establish the effectiveness of using two solvents, TIPS pentacene was grown as follows. Similar to Example 2, a leveled metal plate was uniformly heated using a heavily insulated heat tape. A temperature gradient (approximately 2° C.) was created on the plate by increasing the temperature on the side that was directly on top of the heat tape. A bottom gate silicon substrate with a 250 nm SiO₂ insulation layer was ultra-sonicated in acetone and isopropanol for 10 minutes each to purify it and placed on the metal plate so the temperature gradient could be formed on it. A solution with a concentration of 5 mg/mL of TIPS pentacene in toluene was prepared. A high boiling boing solvent, specifically dimethylformamide (DMF), was mixed into the solution according to the ratio of 1 to 5 (DMF to toluene). Ultrasonic agitation of the solution was performed for 35 minutes. Then, 180 μL of the solution was drop cast onto the silicon substrate subjected to the thermal gradient. Using a 3 mL syringe, approximately 30 drops of toluene were used to anneal the system that was covered with a petri dish to increase the humidity for better crystallization. Solvent evaporation was modulated by the amount of added high boiling point solvent DMF. The TIPS pentacene crystallization occurred over a 45-minute period. Application of the high boiling point solvent to the TIPS pentacene/toluene solution, along with the toluene solvent annealing greatly improved the areal coverage on the substrate as well as the quality of the TIPS pentacene crystals.

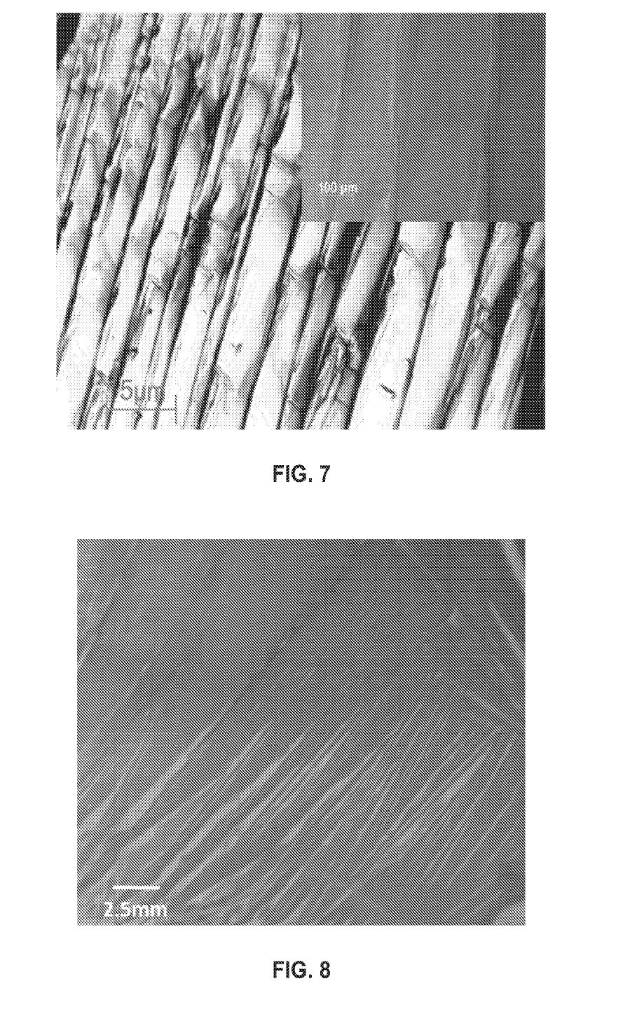

FIG. 7 illustrates an optical image of TIPS pentacene film grown from a double solvent solution (Toluene and DMF) with the application of a temperature gradient. The figure demonstrates uniform crystal orientation, large single crystal sizes, and great areal coverage. The insert is a magnified polarized image of the TIPS pentacene film.

### Example 8

To demonstrate the ability of the methods disclosed herein to be applied to other substrates, a TIPS film was grown exactly as described in Example 7 but on a silicon substrate. FIG. 8 depicts an optical image of TIPS pentacene crystals grown via temperature gradient from a double solvent solution on a silicon substrate. Demonstrated on a broad perspective is the uniform orientation of the crystals.

### Example 9

To demonstrate the use of the method in organic thin film transistor (OTFT) applications, the TIPS pentacene film was grown as described in Example 5 and was used to fabricate transistors. For the fabrication of the OTFT, the substrate was prepared using 60 nm gold electrode source and drain top contacts that were thermally evaporated via a shadow mask on a heavily doped n-type silicon substrate. A high vacuum chamber with a base pressure of approximately 2×10⁻⁷ Torr, was used to perform the gold deposition at a rate of approximately 0.1 nm/s and a pressure of approximately 1×10⁻⁶ Torr. Signatone 1160 Series Probe Station along with the Agilent Technologies B1500A Semiconductor Device Analyzer in ambient temperature were used to characterize the OTFT performance. Typical I_{DS}-V_{DS} output curves were acquired using a gate voltage range of 0V to −20 V in −5V increments. The field effect mobility (μ) of the device in the saturation regime (where V_{DS}=−20 V) as well as the threshold voltage (V_{T}) were extracted from the fitted line to the slope of the (−I_{DS})^{1/2}−V_{GS} transfer characteristics, based on the established MOSFET equation:

$${I}_{DS} = μ {C}_{i} \frac{W}{2 L} {( {V}_{GS} - {V}_{T} )}^{2}$$

where Cᵢ is the specific capacitance of gate insulator, W is the channel width and L is the channel length.

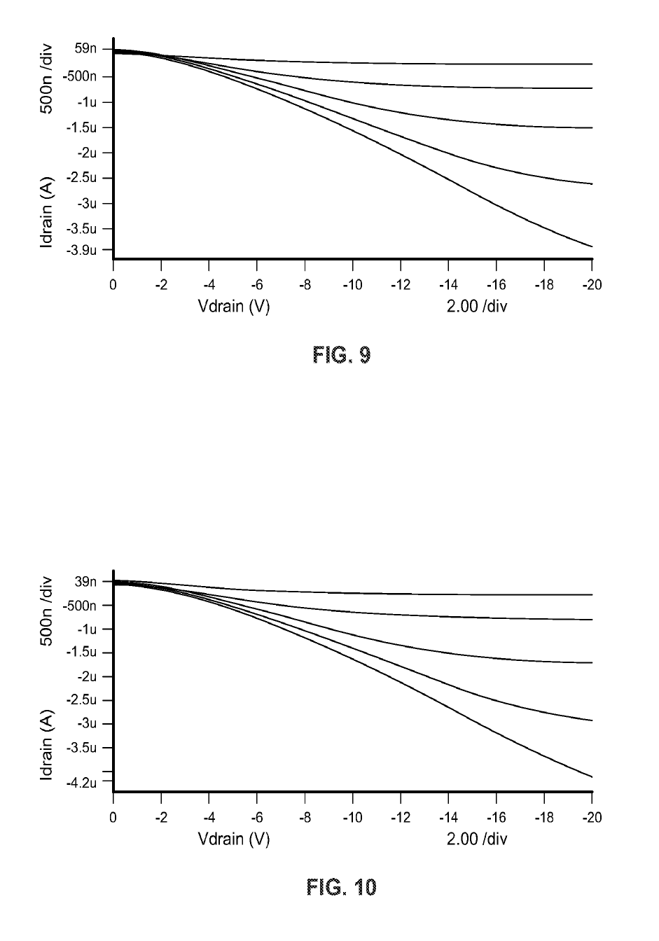

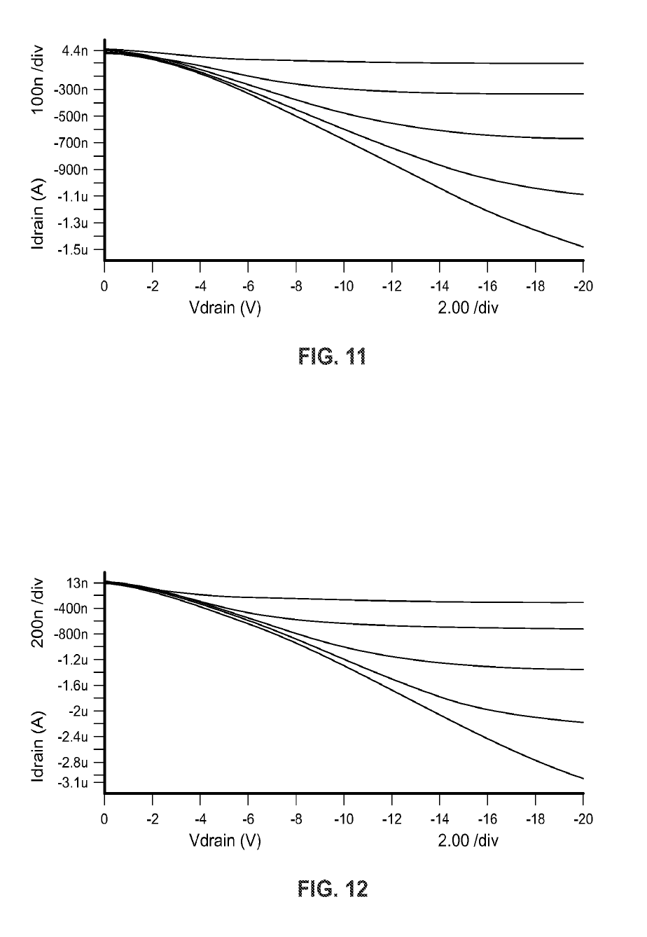

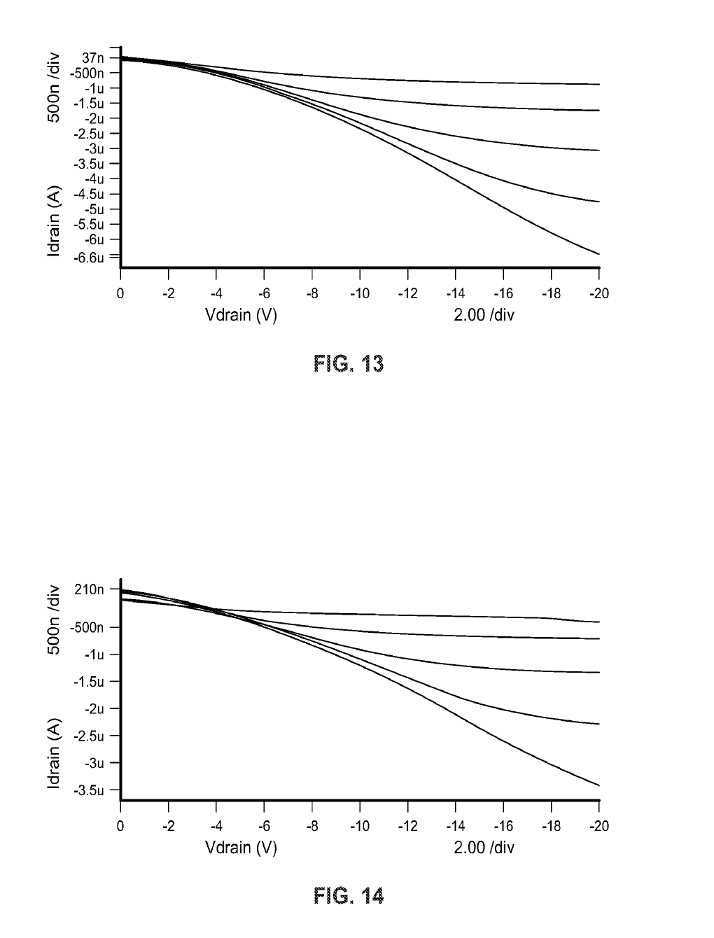

FIGS. 9-14 show the raw data attained from testing 6 transistors made according to this example. Mobility was extracted for each device, and the calculated average mobility along with the standard deviation is 0.048769±0.015012 cm²/Vs.

### Comparative Example 10

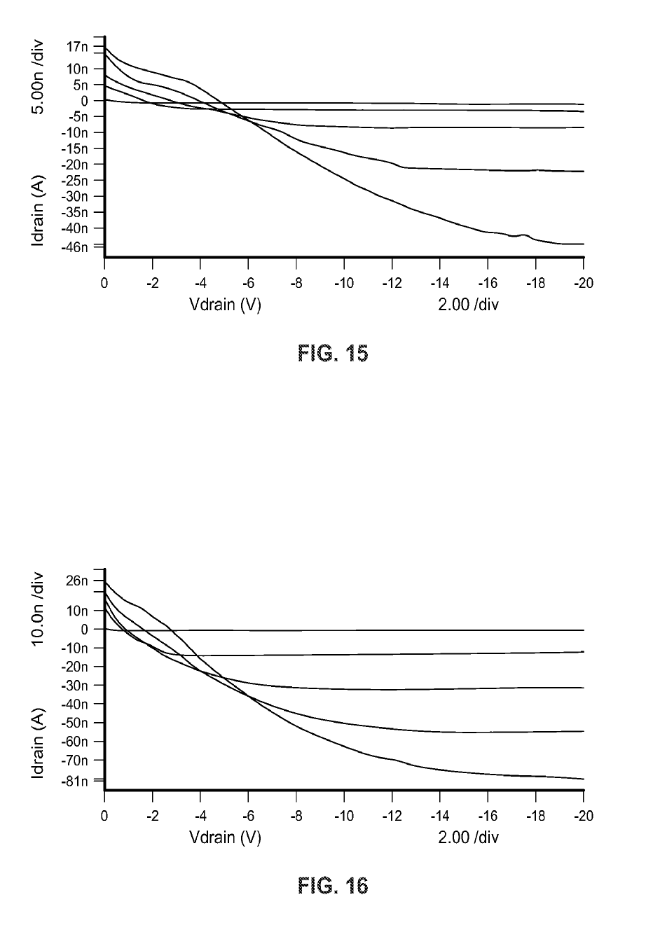

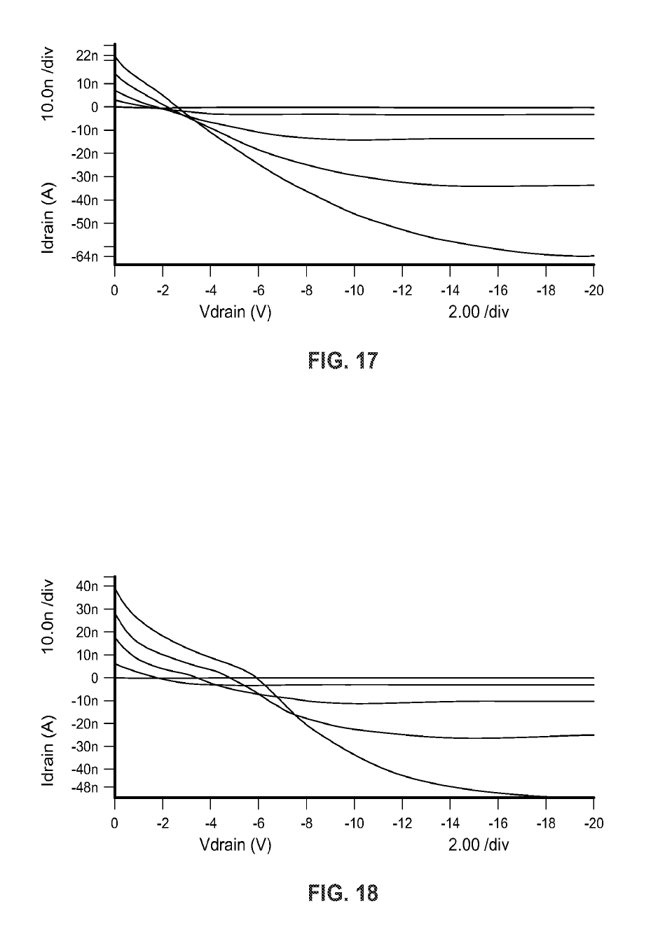

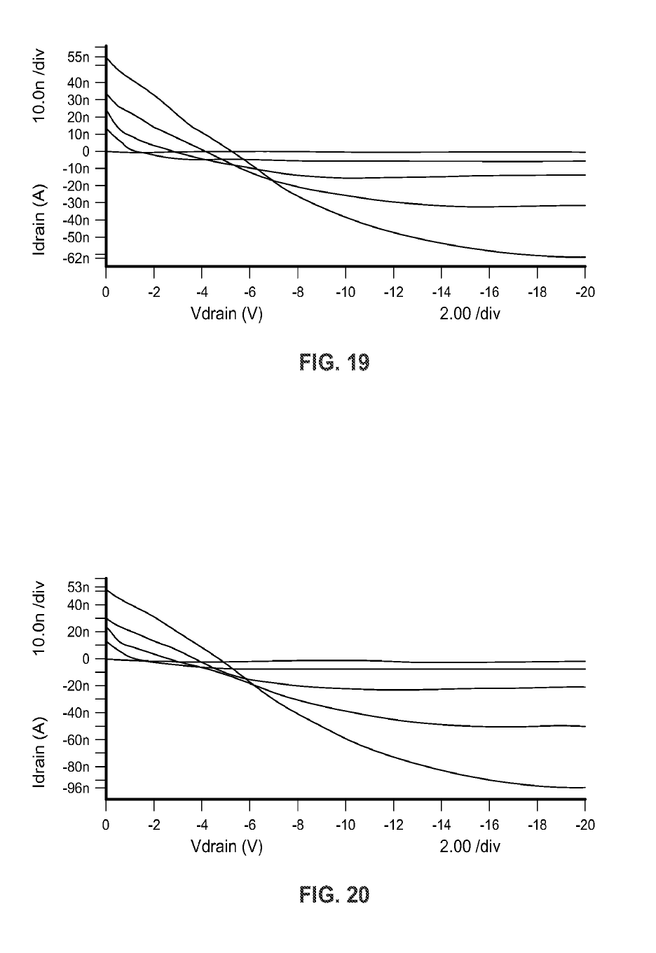

To show the improvement of the methods disclosed herein over drop casting in organic transistor applications, six transistors made using drop cast were tested. I_{DS} versus V_{DS} with different applied gate biases are shown in FIGS. 15-20. Mobility was extracted for each device, and the calculated average mobility along with the standard deviation is 0.0017722±0.00039267 cm²/Vs. This value is 27.5 times less than the average mobility for transistors made using the methods disclosed herein.

1. A method comprising:
establishing a temperature gradient on a substrate to produce a heated substrate having a lower temperature portion at a first temperature and a higher temperature portion at a second temperature; and
applying a solution comprising 6,13-bis(triisopropylsilylethynyl)pentacene to the heated substrate, driving crystallization from the lower temperature portion of the substrate to the higher temperature portion of the substrate.

2. The method of claim 1, wherein the temperature gradient is established on the substrate by
establishing a temperature gradient on a plate such that the plate has a lower-temperature end and a higher-temperature end,
placing the substrate on the plate such that a first portion of the substrate is on the low-temperature end of the plate and a second portion of the substrate is on the high-temperature end of the plate for a set time to produce a heated substrate having a lower-temperature portion at the first temperature and a higher temperature portion at the second temperature.

3. The method of claim 2, wherein the step of establishing a temperature gradient on the plate comprises
heating the plate to the first temperature;
applying increased heat to the second end of the plate to create the higher temperature end.

4. The method of claim 1, wherein the solution further comprises toluene,
a high boiling point solvent, or a mixture thereof.

5. The method of claim 1, wherein the plate comprises metal.

6. The method of claim 1, wherein the substrate comprises silicon.

7. The method of claim 1, wherein the substrate comprises doped silicon.

8. The method of claim 1, wherein the substrate comprises source and drain contacts.

9. The method of claim 1, wherein the first temperature is from 22° C. to 30° C.

10. The method of claim 1, wherein the second temperature is greater than the first temperature by an amount of from 2° C. to 28° C.

11. The method of claim 1, wherein the first temperature is 26° C. and the second temperature is 28° C.

12. The method of claim 1, wherein the solution has a concentration of 5 mg/ml of TIPS pentacene in toluene and a high boiling-point solvent.

13. The method of claim 1, wherein the toluene is present in an amount of from 75 vol % to 85 vol %.

14. The method of claim 1, wherein the high boiling-point solvent is present in an amount of from 15 vol % to 25 vol %.

15. The method of claim 1, wherein the high boiling-point solvent is dimethyl formamide.

16. The method of claim 1, wherein the solution is applied to the substrate by drop casting.

17. Well-oriented 6,13-bis(triisopropylsilylethynyl)pentacene crystals produced by the method of claim 1.

18. A film comprising the well-oriented 6,13-bis(triisopropylsilylethynyl)pentacene crystals of claim 17.

19. A transistor comprising the well-oriented 6,13-bis(triisopropylsilylethynyl)pentacene crystals of claim 17.

20. A transistor comprising the film of claim 18.

21. The transistor of claim 19, wherein the transistor has an extracted mobility of from 0.015-cm²Ns to 0.06 cm²Ns.

22. The transistor of claim 21, wherein the extracted mobility is from 0.03 cm²Ns to 0.05 cm²Ns.

23. The transistor of claim 19, wherein V_{Th} is from 4 V to 11 V.

24. The transistor of claim 23, wherein V_{Th} is from 6 V to 9 V.
